(19) United States
(12) Patent Application Publication
(10) Pub. No.: US 2013/0050915 A1
(43) Pub. Date: Feb. 28, 2013

(54) INTERNAL STRUCTURE FOR ELECTRONIC DEVICE AND ELECTRONIC DEVICE USING THE SAME

(71) Applicants: ZI-MING TANG, Shenzhen City (CN); GANG FENG, Shenzhen City (CN); DENG HE, Shenzhen City (CN); FA-GUANG SHI, Shenzhen City (CN)

(72) Inventors: ZI-MING TANG, Shenzhen City (CN); GANG FENG, Shenzhen City (CN); DENG HE, Shenzhen City (CN); FA-GUANG SHI, Shenzhen City (CN)

(73) Assignees: HON HAI PRECISION INDUSTRY CO., LTD., Tu-Cheng (TW); FU TAI HUA INDUSTRY (SHENZHEN) CO., LTD., ShenZhen City (CN)

(21) Appl. No.: 13/303,141

(22) Filed: Nov. 23, 2011

(30) Foreign Application Priority Data
Aug. 31, 2011 (CN) 201110255045.X

(51) Int. Cl. H05K 5/00; H05K 7/18

(52) U.S. Cl. 361/679.01; 312/223.1

(57) ABSTRACT

An internal structure for an electronic device includes a fixed frame, and a plurality of magnetic assemblies. A plurality of mounting portions are defined in the inner wall of the fixed frame. Each magnetic assembly includes a magnetic member and an elastic element. Both the magnetic member and the elastic element are assembled in the mounting portion. The magnetic member is sandwiched between the inner wall of the fixed frame and the elastic element.

### BACKGROUND

1. Technical Field

The present disclosure relates generally to an internal structure for an electronic device, and an electronic device using the internal structure.

2. Description of Related Art

The display panels of portable electronic devices such as mobile phones, tablet computers, are vulnerable to scratches and other damages. Therefore, a protective cover is usually employed on the electronic device for protection. The protective cover covers the display panel when the electronic device is not being used. An internal structure is usually assembled in the electronic device for the convenient installation of the protective cover. However, some of the internal structures are complex, and the installation of the protective cover is inconvenient.

Therefore, there is room for improvement within the art.

### BRIEF DESCRIPTION OF THE DRAWINGS

The elements in the drawings are not necessarily drawn to scale, the emphasis instead placed upon clearly illustrating the principles of the present disclosure. Moreover, in the drawings, like reference numerals designate corresponding parts throughout the several views.

FIG. 1 is an isometric view of an electronic device in one embodiment.

FIG. 2 is an exploded, isometric view of the electronic device of FIG. 1

FIG. 3 is an exploded, isometric view of the body of the electronic device of FIG. 2.

### DETAILED DESCRIPTION

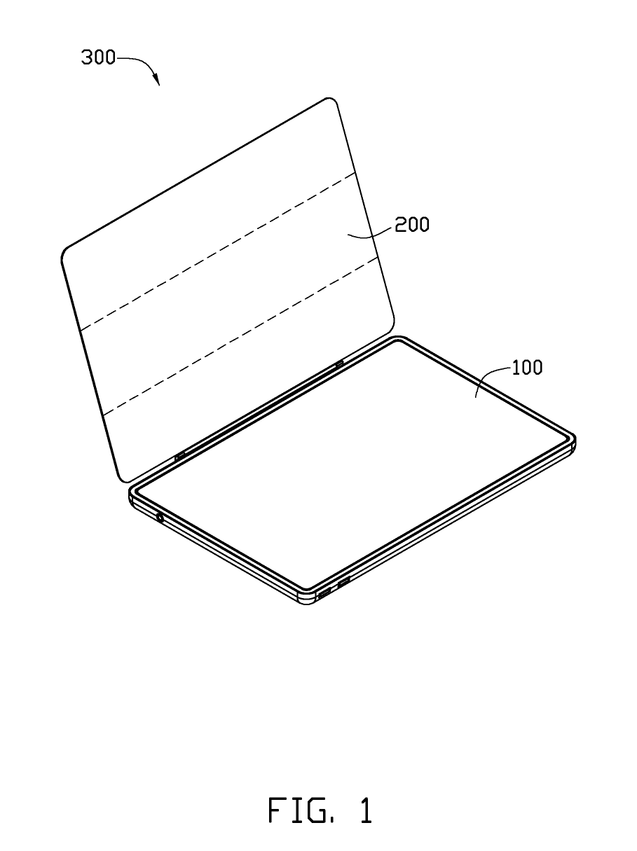

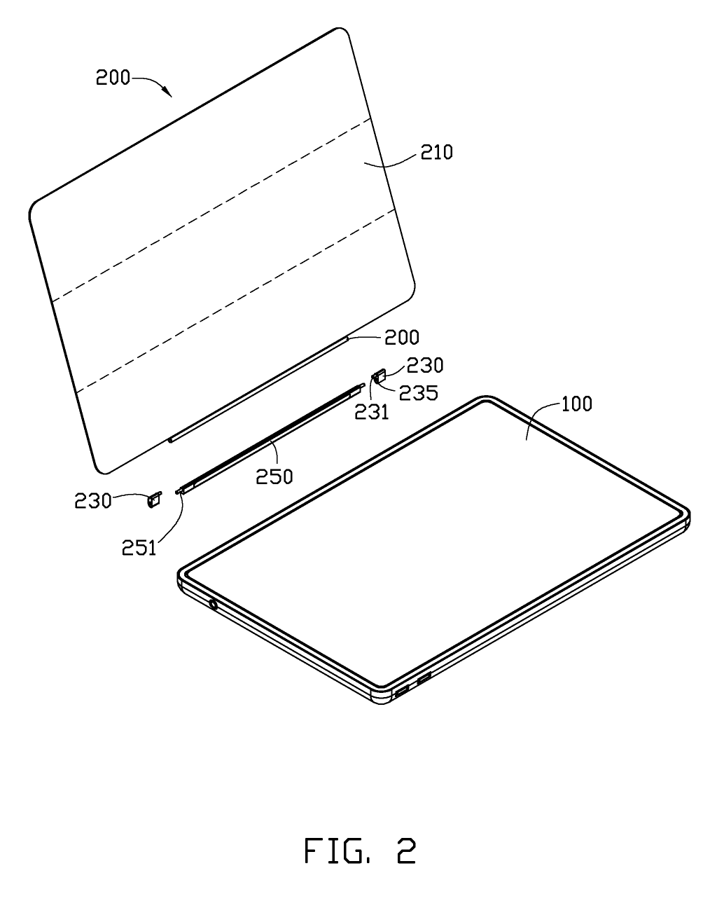

Referring to FIGS. 1 and 2, an embodiment of an electronic device 300 includes a body 100 and a protective cover 200. The protective cover 200 is detachably installed on the body 100 by means of a hinge.

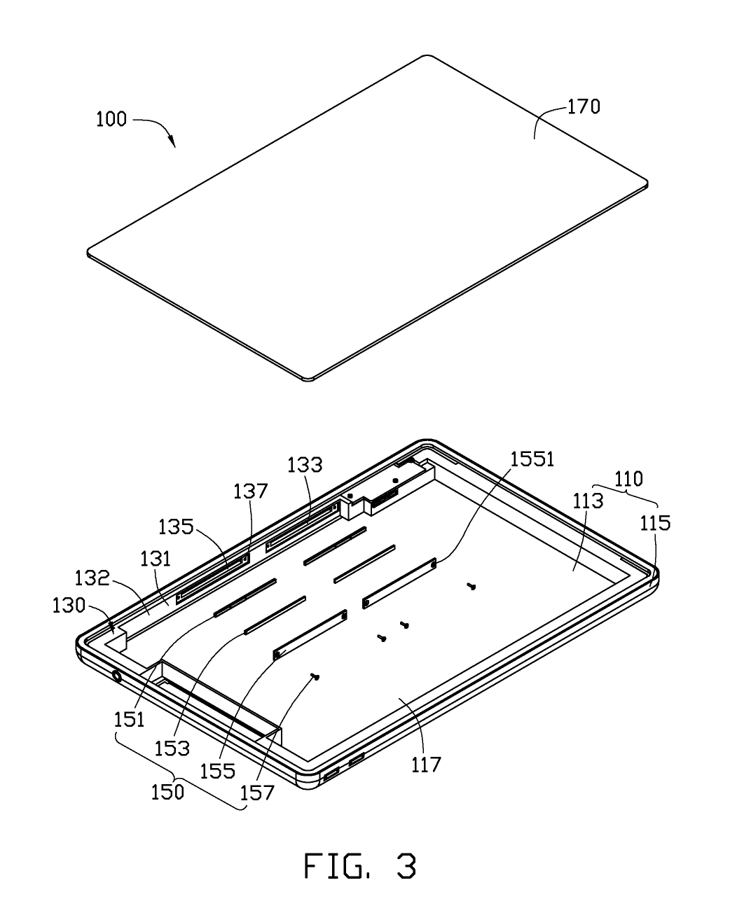

Referring also to FIG. 3, the body 100 includes a housing 110, an internal structure 130, and a display panel 170. The internal structure 130 and the display panel 170 are assembled in the housing 110. The display panel 170 is positioned above the internal structure 130. The body 100 contains other functional structures and components which are not shown and are not described here.

In the illustrated embodiment, the housing 110 is substantially rectangular. The housing 110 includes a base 113 and a sidewall 115 substantially perpendicularly extending from an edge of the base 113. The base 113 and the sidewall 115 cooperatively form a receiving space 117 to receive the internal structure 130, the display panel 170 and the other functional structures.

The internal structure 130 includes a fixed frame 131 and a plurality of magnetic assemblies 150. The magnetic assemblies 150 are received in the fixed frame 131. The fixed frame 131 is a substantially rectangular frame. The fixed frame 131 is assembled in the housing 110 and is positioned adjacent to the sidewall 115 of the housing 110 to provide a firm support base for the display panel 170. A plurality of mounting portions 133 are formed in an inner wall 132 of the fixed frame 131. In the illustrated embodiment, two mounting portions 133 are formed in the inner wall 132 of the fixed frame 131. A receiving groove 135 is defined in the center of the mounting portion 133. The receiving groove 135 is substantially rectangular. A fixing hole 137 is defined at both ends of each of the two mounting portions 133.

The magnetic assemblies 150 are positioned in the mounting portions 133 to provide a magnetic attraction for the protective cover 200. In the illustrated embodiment, two magnetic assemblies 150 are each positioned in each of the two mounting portions 133. Each magnetic assembly 150 includes a magnetic member 151, an elastic element 153, an installing member 155, and two fastening members 157. The magnetic member 151 is received in the receiving grooves 137. In the illustrated embodiment, the magnetic member 151 is a magnet. The elastic element 153 is also substantially rectangular and received in the receiving groove 135 together with the magnetic member 151. The elastic element 153 is sandwiched between the magnetic member 151 and the installing member 155. The elastic element 153 is made of amorphous silicon dioxide. The installing member 155 is substantially a rectangular piece and is fixed in the mounting portion 133 for covering the receiving groove 135. Two fixing holes 1551 are defined in opposite ends of the installing member 155 to correspond to the two fixing holes 137 of the mounting portion 133. In the present embodiment, the installing member 155 is made of steel. The fastening member 157 passes through the fixing hole 1551 and is fixed in the fixing hole 137. In the present embodiment, the fastening member 157 is a screw.

The display panel 170 is substantially rectangular, and displays a plurality of images.

Referring also to FIG. 2, the protective cover 200 is detachably installed in the sidewall 115 by means of a hinge mechanism, to protect the display panel 170. The protective cover 200 includes a cover body 210, two rotational members 230, and a magnetically-responsive element 250. In the illustrated embodiment, the cover body 210 can be folded. A connecting portion 211 is positioned as an extension from one side of the cover body 210. The two rotational members 230 are pivotally coupled with the connecting portion 211. A connecting shaft 231 is formed in one end of the rotational member 230. A rotational hole 235 is defined in the rotational member 230 under the connecting shaft 231. The magnetically-responsive element 250 is rotatably connected to the two rotational members 230 to provide a strong but non-permanent attachment by means of magnetic attraction force with the body 100. Two rotational shafts 251 are formed in the two ends of the magnetically-responsive element 250 for connecting with the rotational member 230. Adhering units (not shown) are positioned in the magnetically-responsive element 250. In the illustrated embodiment, two adhering units which are magnets are arranged so as to be capable of achieving a close proximity with the two magnetic members 151 of the body 100.

In assembly of the electronic device 300, the fixed frame 131 is firstly fixed to the sidewall 115 in the receiving space 117 of the housing 110. The magnetic member 151 is positioned into the receiving groove 135. Then, the elastic element 153 is also received in the receiving groove 135, and is partially exposed from the receiving groove 135. The installing member 155 is fixed to the two fastening members 157 in the mounting portion 133, and the magnetic member 151 is pressed close to the bottom surface of the receiving groove 135. The display panel 170 is fixed in the housing 110 above the fixed frame 131. At last, the protective cover 200 is attracted by the magnetic member 151 and installed on the body 100.

The protective cover 200 can be easily removed from the body 100 when the electronic device 300 is used. The protective cover 200 also can be folded and served as a bracket for supporting the body 100. The cover body 210 covers the display panel 170 when the electronic device 300 is not being used, for additional protection.

The magnetic member 151 of the internal structure 130 can be pressed close to the bottom surface of the receiving groove 135, and the internal structure 130 is connected to the protective cover 200 through the magnetic attraction between the magnetic member 151 and the magnetically-responsive element 250. The internal structure 130 is simple, and connects conveniently with the protective cover 200.

It is believed that the present embodiments and their advantages will be understood from the foregoing description, and it will be apparent that various changes may be made thereto without departing from the spirit and scope of the disclosure or sacrificing all of its material advantages.

What is claimed is:

1. An internal structure, comprising:
a fixed frame comprising a plurality of mounting portions defined in the inner wall of the fixed frame; and
a plurality of magnetic assemblies, and each magnetic assembly comprising a magnetic member and an elastic element, both of the magnetic member and the elastic element received in the mounting portion, wherein the magnetic member is sandwiched between the inner wall of the fixed frame and the elastic element.

2. The internal structure of claim 1, further comprising an installing member fixed in the mounting portion, wherein the elastic element is sandwiched between the magnetic member and the installing member.

3. The internal structure of claim 1, wherein a receiving groove is defined in the mounting portion, and the magnetic member with the elastic element are received in the receiving groove.

4. The internal structure of claim 1, wherein the magnetic member is a magnet.

5. The internal structure of claim 1, wherein the elastic element is made of amorphous silicon dioxide.

6. An electronic device, comprising:
a body comprising:
a housing,
an internal structure assembled in the housing, comprising:
a fixed frame comprising a plurality of mounting portions defined in the inner wall of the fixed frame; and
a plurality of magnetic assemblies, and each magnetic assembly comprising a magnetic member and an elastic element, both of the magnetic member and the elastic element are received in the mounting portion, wherein the magnetic member is sandwiched between the inner wall of the fixed frame and the elastic element; and
a display panel assembled in the housing and positioned above of the internal structure.

7. The electronic device of claim 6, further comprising an installing member fixed in the mounting portion, wherein the elastic element is sandwiched between the magnetic member and the installing member.

8. The electronic device of claim 6, wherein a receiving groove is defined in the mounting portion, and the magnetic member and the elastic element are received in the receiving groove.

9. The electronic device of claim 6, further comprising a protective cover detachably installed on the body.

10. The electronic device of claim 9, wherein the protective cover is rotatably installed on the body.

11. The electronic device of claim 10, wherein the protective cover includes a cover body, two rotational members, and a magnetically-responsive element, the two rotational members are pivotally coupled with the cover body, the magnetically-responsive element is rotatably connected with the two rotational members.

12. The electronic device of claim 11, wherein the magnetically-responsive element is capable of being magnetically attracted with the magnetic member of the body.

13. The electronic device of claim 11, wherein a connecting portion is positioned outward from one side of the cover body, and the two rotational member are pivotally coupled with the connecting portion.
